(19) United States
(12) Patent Application Publication
(10) Pub. No.: US 2007/0170968 A1
(43) Pub. Date: Jul. 26, 2007

(54) Device for transmitting electromagnetic signals and application of said device

(75) Inventor: Detlef Zimmerling, Eberstadt (DE)

Correspondence Address: MCGRATH, GEISSLER, OLDS & RICHARDSON, PLLC, P.O. BOX 1364, FAIRFAX, VA, 22038-1364, US

(73) Assignee: ATMEL Germany GmbH

(21) Appl. No.: 11/657,533

(22) Filed: Jan. 25, 2007

(30) Foreign Application Priority Data
Jan. 25, 2006 (DE) DE 102006003474.0

(51) Int. Cl. H03H 11/26

(52) U.S. Cl. 327/283

(57) ABSTRACT

A device is provided for transmitting electromagnetic signals between at least one first and at least one second functional unit, especially in the high frequency range. The device includes an electrically insulating substrate with a top and a bottom, a first electrically conductive layer of a first coating material on the bottom of the substrate, which layer can be connected to a reference voltage, and a second electrically conductive layer of a second coating material on the top of the substrate. The second electrically conductive layer can be, in at least one region, of fields of the second coating material that are spatially separated from one another and electrically insulated with respect to one another. Each of the fields can have an equal, predetermined capacitance relative to the first electrically conductive layer on an area-by-area basis, and for a transformation behavior of the device for impedance matching to be attainable in a targeted manner through the provision of electrically conductive connections between a number of these fields on a top of the second conductive layer.

This nonprovisional application claims priority under 35 U.S.C. §119(a) on German Patent Application No. DE 102006003474, which was filed in Germany on Jan. 25, 2006, and which is herein incorporated by reference.

### BACKGROUND OF THE INVENTION

1. Field of the Invention

The present invention relates to a device for transmitting electromagnetic signals between at least one first and at least one second functional unit, especially in the high frequency (HF) range, having, for example, an electrically insulating substrate with a top and a bottom, a first electrically conductive layer of a first coating material on the bottom of the substrate, which layer can be connected to a reference voltage, and a second electrically conductive layer of a second coating material on the top of the substrate, wherein the second conductive layer is designed in the form, in at least one region, of fields of the second coating material that are spatially separated from one another and electrically insulated with respect to one another.

The invention also relates to a method for producing an impedance transformation network, a method for developing circuit arrangements (prototype development), and applications of the inventive device.

2. Description of the Background Art

In order to match input and output impedances of electrical functional units that stand in operative connection with one another, it is common practice to place what is called a transformation or matching network between the functional units. This network represents a transformer line and generally includes a number of discrete electronic components such as capacitors, coils, and the like, in order to transform, i.e., match to one another, the impedances of the connected assemblies/functional units in this way. In the course of measuring assemblies/functional units, the measurement contacts of the measurement fixtures must also be compensated as well.

From WO 94/02310 A1 is known a device of the aforementioned type in the form of a printed circuit board having at least one internal capacitor with top and bottom conductive layers and an insulating material located between them. The capacitor is arranged in the interior of the circuit board, and serves to suppress voltage fluctuations as a bypass capacitor for electronic units present on the board. U.S. Pat. No. 5,870,274 A also discloses a comparable device.

U.S. Pat. No. 5,817,533 A describes a method for producing capacitors in which a top electrode of the capacitor is designed in the form of separate, square fields, thus producing a number of component capacitors. These capacitors are tested individually, and only fault-free component capacitors are subsequently connected in an electrically conductive fashion to form an overall capacitor.

At high frequencies of the electromagnetic signals used, for example in a region of 2 GHz and higher, i.e. in the microwave region, discrete components can only be used for impedance matching to a limited extent, since they do not exhibit real behavior at the aforementioned high frequencies. In this regard, do not exhibit real behavior means, for example, that a capacitor does not have purely capacitive properties, but also has inductive and resistive properties at the same time, so that the corresponding equivalent schematic for such a component would require many interacting individual components.

### SUMMARY OF THE INVENTION

It is therefore an object of the present invention to deal with the problem of impedance matching in the transmission of electromagnetic signals. In this regard, it is an object to produce a device by means of which impedance matching can be achieved in a simple and reproducible manner for functional units having signal interactions, even at the aforementioned high frequencies, preferably up to a minimum of 4 GHz.

In addition, a method for achieving suitable impedance matching and a method for developing circuit arrangements (prototypes) at the aforementioned high frequencies, preferably up to a minimum of 4 GHz, are also to be specified.

The object is attained with regard to a first embodiment of the present invention by a device in that each of the fields has a substantially equal, predetermined capacitance relative to the first electrically conductive layer on an area-by-area basis, and in that a transformation behavior of the device for impedance matching can be attained in a targeted manner through the provision of electrically conductive connections between a number of these fields on a top of the second conductive layer.

Each of the fields has a specific capacitance resulting from the first electrically conductive layer located above the bottom of the substrate, the capacitance depending in particular on the field dimensions, the substrate thickness and the relative permeability of the substrate material. In this way, connections are produced between the functional units by means of conductive connections from the aforementioned fields to continuous lines and stubs branching off therefrom, with each connection having a specific capacitance connected in parallel based on the number and position of the fields connected to stubs, representing a means for impedance matching that is considered appropriate by those skilled in the art. Accordingly, the fields of the inventive device, which are spatially separated from one another and are electrically insulated from one another, each function as a type of “unit capacitor” which can be connected in a highly flexible manner as outlined above into a matching network that is to be created, with the inventive device functioning as a special type of semifinished product for said matching network.

According to a second embodiment of the present invention, a method for producing an impedance transformation network with the use of an inventive device is provided, wherein a first functional unit having a first load impedance is connected in an electrically conductive manner to the second electrically conductive layer in a first region; a second functional unit having a second load impedance is connected in an electrically conductive manner to the second electrically conductive layer in a second region. In the event that the first and second regions are not connected together by a conductive connection from the second coating material, an electrically conductive connection is established between the first and second regions on the top of the second electrically conductive layer, and, proceeding from the conductive connection, a number of stubs that are open at their respective ends are created by connecting a number of respective fields to one another and also to the conductive connection on the top of the second electrically conductive layer with a conductive material, wherein each respective position and number of fields is chosen so as to compensate for a difference between the first and second load impedances.

According to a third embodiment of the present invention, a method for developing circuit arrangements (prototype development) using the inventive device is provided, wherein a plurality of functional units are each connected to the second electrically conductive layer in regions thereof, and wherein at least a plurality of fields are connected to one another with an electrically conductive material on the top of the second electrically conductive layer so that the connected fields stand in operative signal connection with the functional units.

In this regard, the aforementioned connecting of the fields to one another can take place at the surface in a simple way in accordance with the invention, i.e., can take place at the top of the second electrically conductive layer through the application of suitably positioned tin bridges made of tin solder or by the placement of a suitably movable and adjustable shorting conductor. To this end, provision is made in a further embodiment of the inventive device that the fields can be connected to one another in an electrically conductive manner at the top of the electrically conductive layer.

According to the invention, the second conductive layer can be made of copper, wherein the aforementioned structuring is produced by standard etching techniques, for example.

In order to achieve an easily plannable and clear matching capability of the inventive device, in particular for the user, provision is made in a further embodiment of the inventive device for the fields to have like dimensions on a region by region basis and/or be arranged in a grid. The grid here preferably has a regular grid structure, which is designed as a square grid in the course of a further embodiment of the inventive device, so that all fields represent identical capacitors in principle on the basis of their identical dimensions.

In order to additionally permit, in a simple way, a direct connection at first between the two functional units whose impedances are to be matched, an embodiment of the inventive device provides that the device has at least one strip of an electrically conductive coating material that is continuous and is electrically insulated from the field regions of the second electrically conductive layer. The electrically conductive coating material of this strip is preferably the second coating material, so that the second electrically conductive layer and the continuous strip hasf the same coating material, which means a significant simplification in terms of production.

In a further embodiment, provision is made that it has at least two regions with fields of the second coating material that are separated from one another by the continuous strip.

In order to permit the simplest possible usage of the inventive device, and additionally permit its incorporation and long-term use in electronic devices, a further embodiment of the inventive device provides that the substrate is designed in the form of a substrate plate, i.e., flat or plate-shaped. FR4 or any other material suitable for HF applications can be used as the plate material, for example.

To achieve increased flexibility in the possible application of the inventive device, in circuit development, for example, provision can additionally be made in further embodiment that electrical functional units, in particular discrete electrical components, can be connected in an electrically conductive manner using the second coating material, for example, by soldered connections. In other words, according to the invention, the fields of the inventive device serve as development support points for the construction and development of complex electronic circuit arrangements, in a manner analogous to conventional circuit boards.

According to an embodiment of the inventive device, the first electrically conductive layer can be connected to a reference voltage, for example ground, wherein the fields of the second layer, as mentioned above, each have a predetermined capacitance with respect to the first layer. According to one example embodiment of the present invention, this predetermined capacitance can be approximately 0.3 pF. However, any other capacitance value is, in principle, equally suitable for attaining the aforementioned object.

In order to ensure the largest possible matching capability for the inventive device, another embodiment provides that the continuous strip is designed as a line with a predetermined ohmic resistance, preferably as a 50 ohm line for standard applications. If, in addition, the dimensions of the individual fields are chosen in agreement with a corresponding dimension (width) of the continuous strip, then in the course of an extremely preferred further development of the inventive device the result will be that at least a number of fields of the second electrically conductive layer that are grouped by area will have the same ohmic resistance as the continuous strip, so that, in turn, it is possible to produce a line having the same predetermined ohmic resistance, thus preferably a 50 ohm line again, by suitably combining fields.

The numeric values mentioned above can be achieved in the case where FR4 is used as the substrate material, for example, in that a value d=1.5 mm is chosen for the substrate thickness and an edge length k=2.54 mm is chosen for the square fields. Alternatively, the value pair d=0.5 mm/k=0.83 mm is also achievable, for example. According to one example embodiment of the present invention, the isolating structures located between the fields of the second electrically conductive layer as well as between the fields and the continuous strip have a width of 1/10 k.

Advantageously, provision can also be made within the scope of a further embodiment of the inventive device that at least the second coating material is removable from the substrate in regions, in particular by mechanical means, to create additional electrical isolating structures. Such an embodiment of the inventive device further increases its flexibility of use in the creation of complex prototypes and circuit arrangements.

As already noted above, the inventive device can advantageously be used, in particular to create an impedance transformation network, in particular for HF applications. To this end, according to the invention a first electrical functional unit having a first load impedance is connected in an electrically conductive way in a first region to the second electrically conductive layer. In addition, a second functional unit having a second load impedance is connected in an electrically conductive way to the second electrically conductive layer. In order to permit signal transmission between the first and second functional units to take place at all, an electrically conductive connection is established between the first and second regions at the top of the second electrically conductive layer in the event that the first and second regions are not already connected together by a conductive connection made of the second coating material. In particular, this (existing) electrically conductive connection between the first and second regions can be the aforementioned continuous strip according to an embodiment of the inventive device, to which both the first and second functional units are connected. Subsequently, proceeding from the created or existing conductive connection, a number of stubs that are open at their respective ends are created by connecting a number of respective fields to one another and also to the conductive connection on the top of the second electrically conductive layer with an electrically conductive material. Each such stub constitutes a capacitor that is connected in parallel with the connection between the two functional units in accordance with the invention. In order to achieve the desired impedance match in this way, each position and/or number of fields to be connected is chosen such that a difference between the first and second load impedances is compensated. This physically corresponds to the parallel connection of a capacitor using discrete components.

Furthermore, the inventive device can also be used generally for developing circuit arrangements or for prototype development, in particular for HF applications. To this end, a plurality of functional units are each connected in an electrically conductive manner to the second electrically conductive layer in regions thereof. Moreover, adjacent thereto, at least a number of fields are connected to one another with an electrically conductive material at the top of the second electrically conductive layer, so that the connected fields stand in operative signal connection with the functional units. Furthermore, in the course of an extremely preferred application of the inventive device, discrete electronic components such as resistors, capacitors, LEDs, switches, etc. can also be electrically conductively connected to fields of the second electrically conductive layer to create complex prototypes/circuit arrangements such as bandpass filters, high-pass filters, low-pass filters, resonant circuits, series resonant circuits, amplifiers, etc., so that the connected fields stand in operative signal connection with the functional units. Provision can be made in this regard for the connection of individual fields to take place in each case by means of a suitable discrete component.

In this way, within the scope of the present invention a device for transmitting electromagnetic signals, in particular in the form of a transformer line, can be built, which in principle uses no discrete components, and thus is not subject to any negative tolerance effects. It is further distinguished by long-term stability and a high degree of reproducibility. In particular, easy compensation of impedance differences is possible in this way in impedance matching. The inventive device was tested for use with signal frequencies up to 4 GHz, and is thus also usable in the microwave region without difficulty; however, it is in no way restricted to this region. Due to its specific design, it is easy to integrate in a layout and, moreover, permits compensation of almost any desired measurement fixture length/line length.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates a schematic top view of a device for transmitting electromagnetic signals, according to an embodiment of the present invention;

FIG. 2 illustrates a section through the inventive device from FIG. 1;

FIG. 3a illustrates a first schematic top view to illustrate possible applications of the inventive device;

FIG. 3b illustrates an equivalent schematic corresponding to the application shown in FIG. 3a;

FIG. 4a illustrates a second schematic top view to illustrate applications of the inventive device;

FIG. 4b illustrates an equivalent schematic corresponding to the application shown in FIG. 4a;

FIG. 4c illustrates a diagram with measured s-parameters of the device shown in FIG. 4a;

FIG. 5a illustrates a third schematic top view to illustrate possible applications of the inventive device;

FIG. 5b illustrates an equivalent schematic corresponding to the application shown in FIG. 5a; and

FIG. 5c illustrates a diagram with measured s-parameters of the device shown in FIG. 5a.

### DETAILED DESCRIPTION

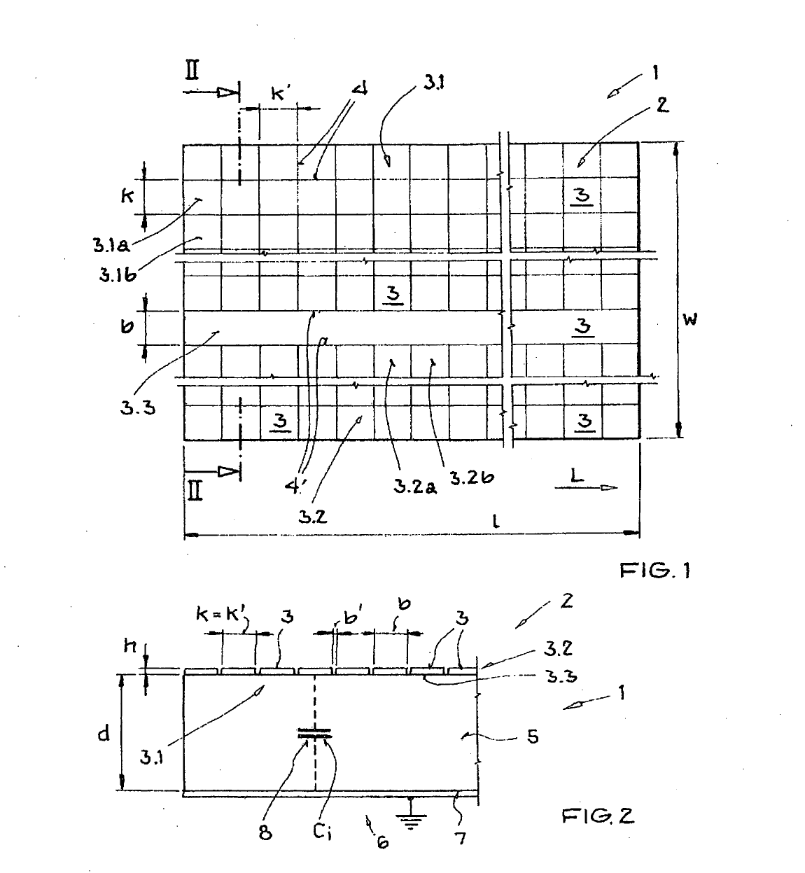

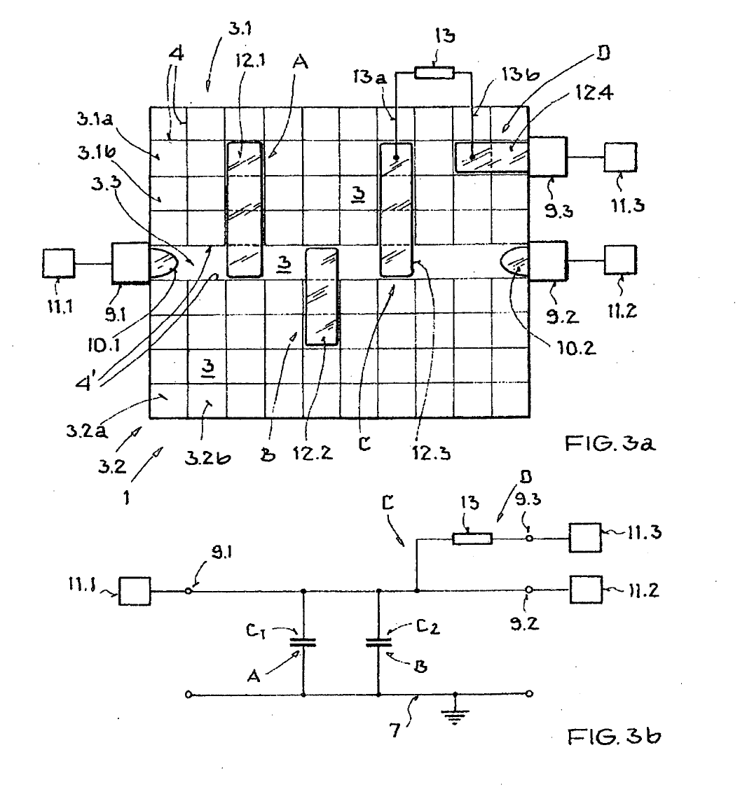

FIG. 1 shows a schematic top view of an inventive device 1 for transmitting electromagnetic signals. The inventive device 1 is designed as a semifinished product in the form of a plate with length l and width w. At its top visible in FIG. 2, the device 1 has an electrically conductive layer 3 made of a suitable material, such as copper or the like. According to the invention, the layer 3 is not uniformly applied to the top 2 of the device 1, but rather is designed in first and second regions 3.1 and 3.2 in the form of an arrangement of fields 3.1a, 3.1b, . . . ; 3.2a, 3.2b, . . . , each of them spatially separated and electrically insulated from one another. According to the example embodiment in FIG. 1, each of the fields has a square shape, i.e. k=k′ for the edge lengths k, k′ of the individual fields 3.1a, 3.1b, . . . ; 3.2a, 3.2b. Moreover, the individual fields are arranged in the form of a regular grid structure. The spatial separation and electrical insulation of the individual fields from one another is accomplished through a grid-like isolating structure 4, which also necessitates the aforementioned regular arrangement of the fields. In this regard, the isolating structure 4 can preferably be created by etching in a standard process.

According to the example embodiment in FIG. 1, the above-described regions 3.1, 3.2 are separated from one another by a continuous strip 3.3, made of the material of the conductive layer 3, extending in the longitudinal direction L of the device 1, wherein the strip 3.3 is electrically insulated on its sides from the regions 3.1, 3.2, or the fields 3.1a, 3.1b, . . . ; 3.2a, 3.2b contained therein, by isolating lines 4′ (linear isolating structure) that also extend in the longitudinal direction L of the device 1. According to the example embodiment shown, the continuous strip 3.3 has a width b that corresponds to the edge lengths k, k′ of the fields, i.e. b=k=k′. The continuous strip 3.3 is also referred to as a “conductive trace” in the discussion below.

FIG. 2 shows a cross-section through the inventive device 1 from FIG. 1, approximately along a line II-II (FIG. 1). Accordingly, the device 1 has, firstly, a support plate 5 (substrate) made of an appropriate electrically insulating material, which can be an epoxy material typically used for manufacturing circuit boards and having suitable dielectric properties, such as FR4 or the like. The support plate 5 has a thickness d. When FR4 is used, this thickness is in a range from 0.5 mm to 1.5 mm for 50-ohm applications according to the invention. On its bottom 6, the device 1 or the support plate 5 is coated with an electrically conductive layer in the form of a copper layer 7. According to one embodiment of the present invention, this layer is connected to a reference voltage, in particular to ground. In addition, the field and strip structures and corresponding isolating structures 4, 4′ described above with reference to FIG. 1 can also be seen at the top 2 of the device 1 or the support plate 5.

According to the invention, the continuous conductive strip 3.3 is designed as a 50-ohm line. Due to the ratio of strip width b and field edge lengths k, k′ chosen, moreover, the individual fields 3.1a, 3.1b, . . . ; 3.2a, 3.2b, . . . each constitute segments of a 50-ohm line in and of themselves, so that further 50-ohm lines in addition to the continuous strip 3.3 can be created in a flexible manner with appropriate connection of individual fields across the isolating structures 4, 4′; this is described in detail below. Furthermore, each of the fields 3.1a, 3.1b, . . . ; 3.2a, 3.2b, . . . constitutes a capacitor 8 with a capacitance Cᵢ to the copper layer 7 (ground), as is indicated in FIG. 2 by dashed lines. The capacitance Cᵢ of each one of these capacitors 8 is preferably approximately 0.3 pF. To this end, the common value for b, k, k′ is preferably 2.54 mm in the case where d=1.5 mm (FR4), and is preferably 0.83 mm in the case where d=0.5 mm (FR4). The thickness h of the conductive layer 3 according to the invention is in the range of, for example, a few micrometers, e.g. h=17 μm or h=35 μm. While the value of h has practically no effect on the capacitance Cᵢ, it determines the resistance of the conductive structures (fields, conductive traces) by way of the cross-sectional area. The isolating structures have a width b′ that is one tenth of the width b, k, k′ of the conductive structures 4, 4′.

Preferred potential applications of the inventive device 1 described above, after the fashion of a semifinished product, are described below with reference to the following FIGS. 3a through 5c.

FIG. 3a shows possible applications of the device 1 described above with reference to FIGS. 1 and 2, initially without concrete circuit application cases. To this end, the device 1 is provided in the region of each of the opposing ends of the continuous conductive trace 3.3 with a connecting device 9.1, 9.2, for example for connecting a suitable plug connector (not shown). The connecting devices 9.1, 9.2 are each attached to the continuous strip 3.3 by a soldered connection 10.1, 10.2. In each case, an electrical functional unit 11.1 or 11.2 is connected to the connecting devices 9.1, 9.2, with a transmission of electromagnetic signals, preferably high frequency electromagnetic signals in the gigahertz range, taking place between the functional units 11.1, 11.2. For example, the first functional unit 11.1 can be a HF signal generator and the second functional unit 11.2 can be a measurement spider/measurement fixture (with attached measuring device, if applicable). Signal transmission between the functional units 11.1, 11.2 thus takes place according to the invention through the continuous trace 3.3 designed as a 50 ohm line. However, high frequency (HF) assemblies, such as the functional units 11.1, 11.2 referred to, typically have complex-valued resistances (impedances) at their respective inputs and outputs, which as a rule are not tuned to the impedance of another assembly/functional unit with which the first functional unit/assembly enters into operative connection, such as is the case in the aforementioned functional units 11.1, 11.2. Additional assemblies located in the signal transmission path between the functional units, such as the measurement contacts of a measurement fixture or the connecting devices 9.1, 9.2 can also contribute to such a mismatch of the impedance. It is necessary, therefore, to transform the impedances at the input and output of HF assemblies in order to match them to one another.

When the inventive device 1 is used, this can be achieved in that a capacitance (is formed of multiple individual capacitances, if applicable) is appropriately connected parallel to the line between the functional units 11.1, 11.2, i.e., in the case of the present invention the continuous conductor trace 3.3. To this end, in the example embodiment in FIG. 3a, in regions A, B starting in each case from the continuous conductive trace 3.3, a plurality of fields in the region 3.1 or 3.2 on the top 2 of the device 1 are connected to one another and to the continuous conductor trace 3.3 in an electrically conductive manner across the isolating structures 4, 4′, for example by the application of tin solder in the corresponding regions A, B, which is represented in general in the present figure and following figures by cross-hatching. In this way, stubs are formed in each case in the regions A, B by the resultant tin bridges 12.1 or 12.2, which stubs represent a capacitor with a corresponding capacitance Cᵢ parallel to the continuous conductive trace 3.3, i.e., the line between the functional units 11.1, 11.2, depending on the position and number of the fields connected. In this context, the tin solder bridges 12.1, 12.2 have almost no influence upon the impedance value of the line, which is dominated by the capacitive component in the HF region of predominant interest here.

As an alternative to the above-described connection method using tin solder, it is also possible to use movable and adjustable shorting elements (not shown) on the top 2 of the device 1. It is advantageous if the latter are cuboid elements made of polystyrene foam, which are practically “invisible” in the HF spectral region, and which are provided with an electrically conductive layer on one cube face, for example by gluing on a piece of copper foil with a certain geometry. By changing the position and size (dimensions of the copper foil) of the capacitance(s) thus produced, almost any point on a Smith chart can be reached according to the invention so that wide matching of impedances is possible. Subsequently, the matching capacitances thus determined can then be implemented permanently by means of tin bridges (see above).

In addition, FIG. 3a shows additional tin bridges 12.3 and 12.4 in the regions C, D, each of which is produced in similar fashion to the tin bridges 12.1, 12.2 described in detail above. Here, the tin bridge 12.3 extends away from the continuous trace 3.3 and perpendicular to its direction of extension, whereas the tin bridge 12.4 in the region D extends parallel to the continuous trace 3.3, and does not contact it. Moreover, the tin bridges 12.3, 12.4 are connected to one another through a discrete electronic component, in this case a resistor 13, whose terminals 13a, 13b are integrated in the tin bridges 12.3, 12.4, so that the fields located thereunder also serve as solder terminals for the resistor 13. Moreover, with the solder bridge 12.4 there is another connecting device 9.3 in the edge region of the device 1, through which another functional unit 11.3 is connected. In this way, in addition to the conductive trace 3.3, further subsections of a 50-ohm line defined by the tin bridges 12.3, 12.4 have been created according to the invention in the aforementioned regions C, D by appropriately connecting fields. With a suitable extension of this basic inventive concept, it is thus possible using the inventive device 1 and suitable discrete components to implement any desired circuit structures, in particular for development of HF circuits or prototypes, for example bandpass filters, high-pass filters, low-pass filters, resonant circuits, series resonant circuits, amplifiers, or the like, which are known per se to those skilled in the art.

FIG. 3b shows a simplified equivalent schematic for the application of the inventive device explained above on the basis of FIG. 3a. Here, like or identical components are labeled with the same reference symbols as in the explanation given above of the inventive device. In particular, the way in which capacitances C, C₂ are connected in parallel to the “actual” line (continuous conductive trace 3.3) in the regions A, B, by means of which capacitances an impedance transformation between the functional units 11.1, 11.2 can be achieved in a flexible manner, is evident from FIG. 3b. The schematic shown is simplified to the extent that only the capacitances realized by means of the tin bridges 12.1, 12.2 (FIG. 3a) are explicitly shown, but not additional components such as inductances or resistances that are also created in the process.

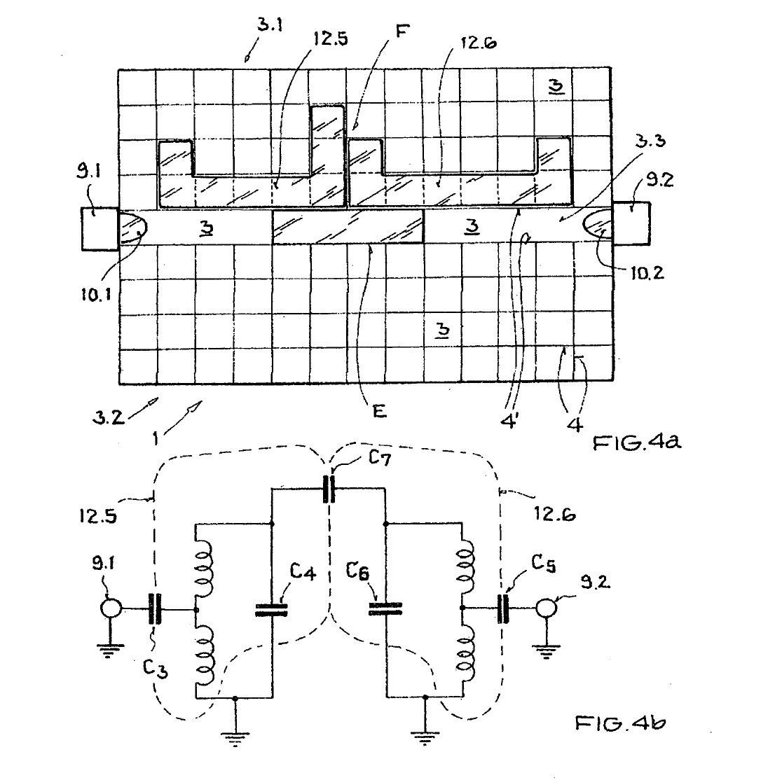

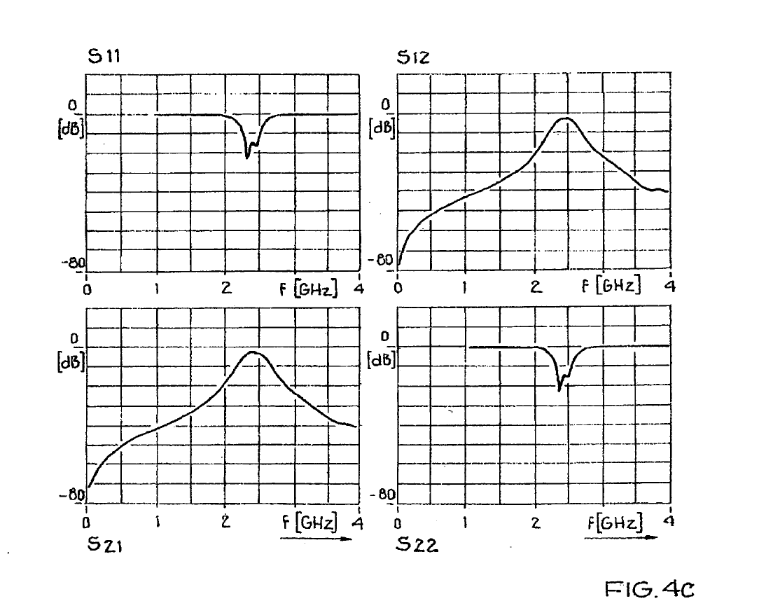

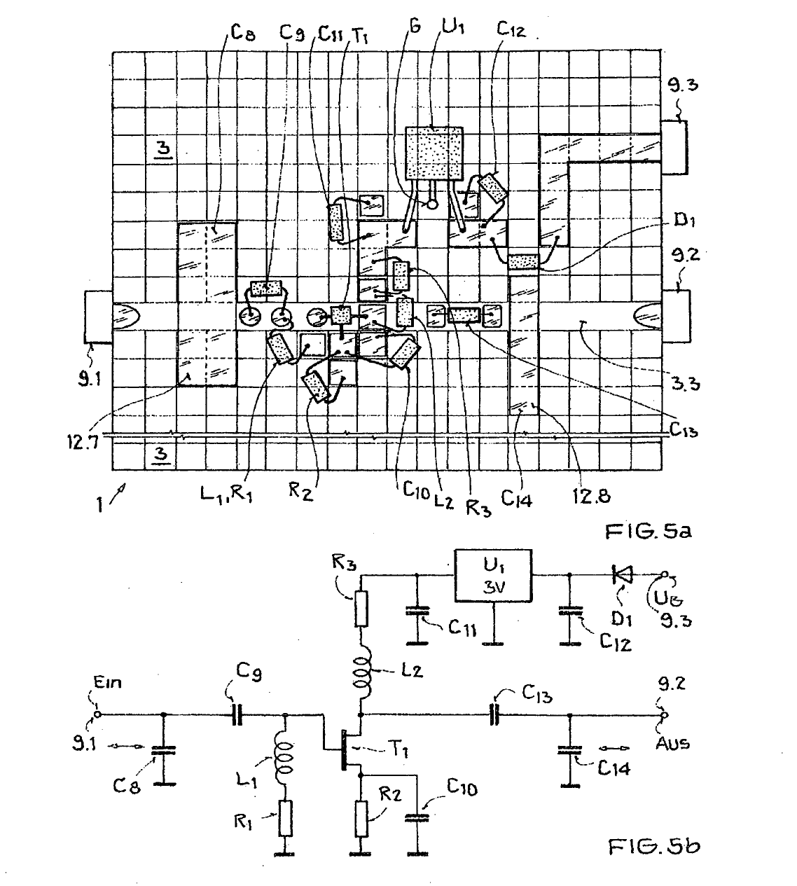

FIG. 4a shows another example application of the inventive device 1 for implementing a two-circuit bandpass filter, for example at a signal frequency of 2.4 GHz. In accordance with the present illustration, connecting devices 9.1, 9.2 are again connected to the trace 3.3 as in FIG. 3a, said connecting devices in turn standing in operative connection with appropriate functional devices 11.1, 11.2. However, in the example application from FIG. 4a, the conductive trace 3.3, which is continuous per se, is broken electrically in a central section E by mechanically removing (scratching) the conductive layer 3. In addition, in the region 3.1—above the trace 3.3—two essentially U-shaped structures 12.5, 12.6 (offset at the ends) in the form of tin bridges are formed, each of which connects a specific number of fields to one another across the isolating structure 4. In this context, the center, i.e. not free, arm of each of the U-shaped structures 12.5, 12.6 is oriented parallel to the conductive trace 3.3. There is no electrically conductive connection either between the tin bridges 12.5, 12.6 and the trace 3.3 or between the bridges 12.5, 12.6 themselves (galvanic isolation, purely capacitive/inductive coupling).

FIG. 4b shows the corresponding equivalent schematic, where once again identical or similar elements are labeled with the same reference symbols. As is evident from FIG. 4b, the capacitors C₃, C₄ are formed by the tin bridge 12.5, or the fields of the device 1 connected thereby, and the ground 7 (capacitor C₄). Similarly, the tin bridge 12.6 is responsible for the existence of the capacitors C₅, C₆. The capacitor C₇ necessary for capacitively coupling the two circuits thus created arises from the closely adjacent arrangement of the tin bridges 12.5, 12.6 in the region F (FIG. 4a). In the present case, the tin bridges 12.5, 12.6 thus constitute what are called resonators, which also have inductive, and of course resistive, properties in addition to the capacitive properties already described, as is also evident from FIG. 4b.

FIG. 4c shows the s-parameters determined for the application, shown in FIG. 4a, b, of the inventive device for producing a two-circuit bandpass filter; these parameters are among the four-pole parameters customary in HF design, and describe the behavior of an electronic component. A two-port network is described by four s-parameters—s₁₁, s₁₂, s₂₁, s₂₂. Here, s₁₁ is the reflection factor at the input with the output terminated (using an appropriate impedance), s₁₂ is the reverse gain with the input terminated, s₂₁ is the forward gain with the output terminated and thus represents the insertion loss, s₂₂ is the reflection factor at the output with the input terminated. In modern high-frequency laboratories, the s-parameters are measured with the aid of a network analyzer (vector network analyzer/VNA) as a function of frequency. The parameters are dimensionless complex numbers, and in practice are specified as magnitude in dB and phase in degrees. Representation in a Smith chart as a locus of frequency is customary. When using the device created within the scope of the present invention, almost any desired points in the Smith chart can be reached, as described above, by appropriate matching of the s-parameters.

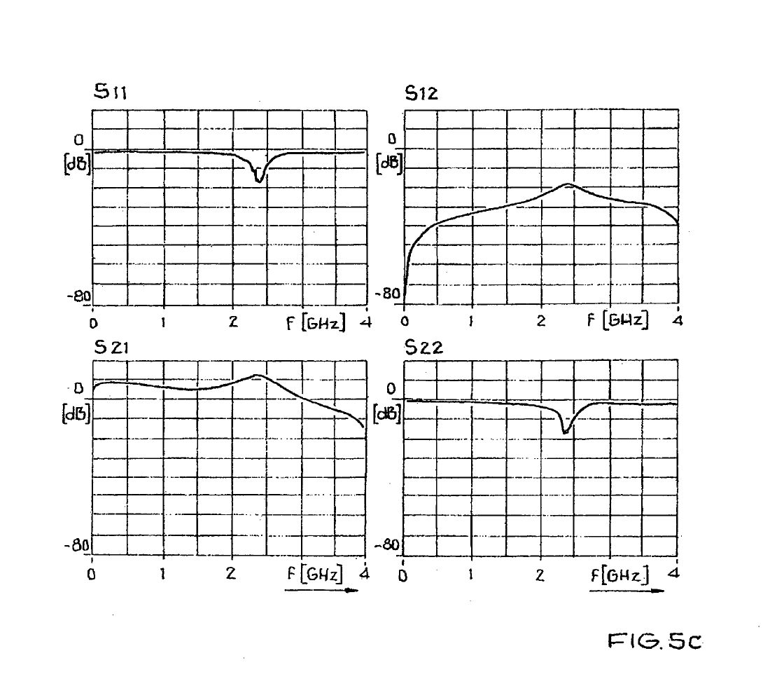

FIG. 5a shows another example application of the inventive device 1 for realizing an amplifier circuit, known per se, whose detailed schematic is shown in FIG. 5b, wherein corresponding elements in the two diagrams, for example capacitors C₈-C₁₄, resistors R₁-R₃, coils L₁-L₂, voltage regulator U₁, transistor T₁ and diode D₁, are labeled with the same reference symbols. According to the present depiction, connection devices 9.1-9.3 for input, output and supply voltage U_{B} again are connected to the trace 3.3 as in FIG. 3a, 4a, and again stand in operative connection with suitable functional units (not shown). As can be seen from FIG. 5a,b, in particular the capacitor C₈ for input impedance matching is formed by tin bridge 12.7 or the fields of the device 1 connected thereby, and by ground 7 (FIG. 2). Accordingly, tin bridge 12.8 is responsible for the existence of the capacitor C₁₄ for output impedance matching. As indicated by the double arrow in FIG. 5b, the two capacitors C₈, C₁₄ are flexibly adaptable in size (geometric dimensions) and position. The other components are designed as conventional discrete components and are soldered onto the inventive device 1 (cross-hatched regions). The ground terminal of the voltage regulator U₁ is connected at G by making a hole through to the ground layer 7 (FIG. 2), as already described above. The other ground connections shown in FIG. 5b can also be implemented in similar fashion.

FIG. 5c shows the s-parameters of the circuit arrangement from FIGS. 5a and 5b, again showing all four s-parameters s₁₁, s₁₂, s₂₁, s₂₂.

The present invention thus offers a variety of circuit design options that are not achievable with other circuit boards, for example experimenter boards with grids of holes or traces. For example, extremely short ground connections can be produced at any desired point of the inventive device in a flexible manner by drilling through the substrate 5 (FIG. 2) and soldering in an electrically conductive connecting element (e.g., a piece of wire; not shown). In addition, a coil can be implemented in a simple manner by application of a spiral-shaped structure of solder, for example.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A device for transmitting electromagnetic signals between at least one first functional unit and at least one second functional unit, the device comprising:
an electrically insulating substrate having a top and a bottom;
a first electrically conductive layer of a first coating material being provided on the bottom of the substrate, which layer is connected to a reference voltage; and
a second electrically conductive layer of a second coating material on the top of the substrate, wherein the second conductive layer in at least one region forms fields of the second coating material that are spatially separated from one another and electrically insulated with respect to one another,
wherein each of the fields has a substantially equal, predetermined capacitance relative to the first electrically conductive layer on an area-by-area basis, and
wherein a transformation behavior of the device for impedance matching is attained in a targeted manner through electrically conductive connections between a number of the fields on the top of the second conductive layer.

2. The device according to claim 1, wherein the fields have substantially equal dimensions on a region by region basis.

3. The device according to claim 1, wherein the fields are arranged in a grid on a region by region basis.

4. The device according to claim 3, wherein the grid has a regular grid structure.

5. The device according to claim 3, wherein the grid is a square grid.

6. The device according to claim 1, wherein at least one strip that is continuous and is electrically insulated from the region of the second layer, is made of an electrically conductive coating material or of the second coating material.

7. The device according to claim 6, further comprising at least two regions with fields of the second coating material that are separated from one another by the continuous strip.

8. The device according to one of claim 1, wherein the substrate is a substrate plate.

9. The device according to claim 1, wherein additional electrical functional units, in particular discrete electrical components, are connected in an electrically conductive manner using the second coating material, in particular by soldered connections.

10. The device according to claim 6, wherein the continuous strip is a line with a predetermined ohmic resistance, preferably as a 50 ohm line.

11. The device according to claim 1, wherein at least a number of fields of the second electrically conductive layer that are grouped by area has substantially the same ohmic resistance as the continuous strip.

12. The device according to claim 1, wherein at least the second coating material is removable from the substrate in regions, in particular by mechanical means, to create additional electrical isolating structures.

13. Use of the device according to claim 1 to produce an impedance transformation network.

14. A method for producing an impedance transformation network with the use of a device according to claim 1, the method comprising:
connecting a first functional unit having a first load impedance in an electrically conductive manner to the second electrically conductive layer in a first region; and
connecting a second functional unit having a second load impedance is connected in an electrically conductive manner to the second electrically conductive layer in a second region;
wherein, in the event that the first and second regions are not connected together by a conductive connection made of the second coating material, an electrically conductive connection is established between the first and second regions on the top of the second electrically conductive layer, and
wherein, proceeding from the conductive connection, a number of stubs that are open at their respective ends are created by using an electrically conductive material to connect a number of respective fields to one another and also to the conductive connection on the top of the second electrically conductive layer, each respective position and number of fields is chosen so as to compensate for a difference between the first and second load impedances.

15. The method according to claim 14, wherein the functional units are each connected with the continuous strip according to claim 6.

16. Use of the device according to claim 1 to develop circuit arrangements.

17. The method according to claim 14, wherein a plurality of functional units are each connected to the second electrically conductive layer in regions thereof, and wherein at least a plurality of fields are connected to one another with an electrically conductive material on the top of the second electrically conductive layer so that the connected fields stand in operative signal connection with the functional units.

18. The method according to claim 17, wherein discrete electronic components such as resistors, capacitors, LEDs, switches, etc. are electrically connected to fields of the second electrically conductive layer, so that the connected fields stand in operative signal connection with the functional units.

19. The method according to claim 17, wherein the connection of individual fields is accomplished by a suitable discrete component.
